(19) United States
(12) Patent Application Publication
(10) Pub. No.: US 2025/0266321 A1
(43) Pub. Date: Aug. 21, 2025

(54) SEMICONDUCTOR DEVICE AND METHOD FOR MANUFACTURING THE SAME

(71) Applicant: TAIWAN SEMICONDUCTOR MANUFACTURING COMPANY LTD., HSINCHU (TW)

(72) Inventors: GUO-HUEI WU, TAINAN CITY (TW); HAO-TIEN KAN, NEW TAIPEI CITY (TW); KUO-NAN YANG, HSINCHU CITY (TW); CHIN-SHEN LIN, TAIPEI CITY (TW); SHUHEI MATSUO, HSINCHU (TW); TUNG-AN LAN, HSINCHU (TW); CHIEN-YING CHEN, CHIAYI COUNTY (TW)

(21) Appl. No.: 18/443,343

(22) Filed: Feb. 16, 2024

(51) Int. Cl. H01L 23/48; H01L 21/768; H01L 27/02

(52) U.S. Cl. CPC H01L 23/481; H01L 21/76898; H10D 89/10

(57) ABSTRACT

A semiconductor device and a method for manufacturing the semiconductor device are provided. The semiconductor device includes a first back metal structure, a first conductive structure, a metal layer structure and a second metal structure. The first back metal structure belongs to a first power domain, and the first back metal structure is formed on a back side of the wafer. The first conductive structure extends in a first direction, is formed above the first back metal structure, and is P-type. The metal layer structure extends in a second direction vertical to the first direction and is formed above the first conductive structure. The second metal structure belongs to a second power domain different from the first power domain.

### BACKGROUND

The present disclosure relates, in general, to semiconductor devices and methods for manufacturing the same. Specifically, the present disclosure relates to semiconductor devices and methods for manufacturing semiconductor devices with a header cell for power delivery.

Integrated circuits that involve semiconductor devices are essential for many modern applications. Technological advances in materials and design have produced semiconductor devices composed of smaller and more complex elements each generation. Although power consumption per element is reduced by miniaturization and reductions in voltage of elements, power consumption of the entire integrated circuit is rising due to increase in the number of elements. Therefore, a novel design of a header cell as a power switch cell is needed to control power delivery and improve compatibility with other functional cells.

### BRIEF DESCRIPTION OF THE DRAWINGS

Aspects of the embodiments of the present disclosure are best understood from the following detailed description when read with the accompanying figures. It should be noted that, in accordance with standard practice in the industry, various structures are not drawn to scale. In fact, the dimensions of the various structures can be arbitrarily increased or reduced for clarity of discussion.

FIG. 1A is a schematic view of a semiconductor device on a wafer, in accordance with some embodiments of the present disclosure.

FIG. 1B is a schematic view of a design layout of another semiconductor device, in accordance with some embodiments of the present disclosure.

FIG. 1C is a schematic view of a design layout of another semiconductor device, in accordance with some embodiments of the present disclosure.

FIG. 1D is a schematic view of a design layout of another semiconductor device, in accordance with some embodiments of the present disclosure.

FIG. 2A is a schematic diagram of a semiconductor device, in accordance with some embodiments of the present disclosure.

FIG. 2B is a schematic diagram of a design layout of a semiconductor device, in accordance with some embodiments of the present disclosure.

FIG. 2C illustrates cross-section views of a semiconductor device along the section lines C2 and D2 in FIG. 2B, in accordance with some embodiments of the present disclosure.

FIG. 3A is a schematic diagram of a semiconductor device, in accordance with some embodiments of the present disclosure.

FIG. 3B is a schematic diagram of a design layout of a semiconductor device, in accordance with some embodiments of the present disclosure.

FIG. 3C illustrates cross-section views of a semiconductor device along the section lines C3 and D3 in FIG. 3B, in accordance with some embodiments of the present disclosure.

FIG. 4A is a schematic diagram of a design layout of a semiconductor device, in accordance with some embodiments of the present disclosure.

FIG. 4B illustrates cross-section views of a semiconductor device along the section lines C4 and D4 in FIG. 4A, in accordance with some embodiments of the present disclosure.

FIG. 5A is a schematic diagram of a design layout of a semiconductor device, in accordance with some embodiments of the present disclosure.

FIG. 5B illustrates cross-section views of a semiconductor device along the section lines C5 and D5 in FIG. 5A, in accordance with some embodiments of the present disclosure.

FIG. 6A is a schematic diagram of a semiconductor device, in accordance with some embodiments of the present disclosure.

FIG. 6B illustrates cross-section views of two semiconductor devices along the section lines C61 and C62, in accordance with some embodiments of the present disclosure.

FIG. 7A is a schematic diagram of a design layout of a semiconductor device, in accordance with some embodiments of the present disclosure.

FIG. 7B is a schematic diagram of a design layout of another semiconductor device, in accordance with some embodiments of the present disclosure.

FIG. 8A is a schematic diagram of a semiconductor device, in accordance with some embodiments of the present disclosure.

FIG. 8B is a schematic diagram of a design layout of a semiconductor device, in accordance with some embodiments of the present disclosure.

FIG. 8C illustrates cross-section views of a semiconductor device along the section lines C8 and D8 in FIG. 8B, in accordance with some embodiments of the present disclosure.

FIG. 9A is a schematic diagram of a design layout of a semiconductor device, in accordance with some embodiments of the present disclosure.

FIG. 9B illustrates cross-section views of a semiconductor device along the section lines C9 and D9 in FIG. 9A, in accordance with some embodiments of the present disclosure.

FIG. 10A is a schematic diagram of a design layout of a semiconductor device, in accordance with some embodiments of the present disclosure.

FIG. 10B illustrates cross-section views of a semiconductor device along the section lines C10 and D10 in FIG. 10A, in accordance with some embodiments of the present disclosure.

FIG. 11A is a schematic diagram of a design layout of a semiconductor device, in accordance with some embodiments of the present disclosure.

FIG. 11B illustrates cross-section views of a semiconductor device along the section lines C11 and D11 in FIG. 11A, in accordance with some embodiments of the present disclosure.

FIG. 12A is a schematic diagram of a design layout of a semiconductor device, in accordance with some embodiments of the present disclosure.

FIG. 12B illustrates cross-section views of a semiconductor device along the section lines C12 and D12 in FIG. 12A, in accordance with some embodiments of the present disclosure.

FIG. 13A is a schematic diagram of a design layout of a semiconductor device, in accordance with some embodiments of the present disclosure.

FIG. 13B illustrates cross-section views of a semiconductor device along the section lines C13 and D13 in FIG. 13A, in accordance with some embodiments of the present disclosure.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features can be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “upper,” “on” and the like, can be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus can be otherwise oriented (rotated 90 degrees or at other orientations) and the spatially relative descriptors used herein may likewise be interpreted accordingly.

As used herein, although terms such as “first,” “second” and “third” describe various elements, components, regions, layers and/or sections, these elements, components, regions, layers and/or sections should not be limited by these terms. These terms may only be used to distinguish one element, component, region, layer or section from another. Terms such as “first,” “second” and “third” when used herein do not imply a sequence or order unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the terms “substantially,” “approximately” and “about” generally mean within a value or range that can be contemplated by people having ordinary skill in the art. Alternatively, the terms “substantially,” “approximately” and “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

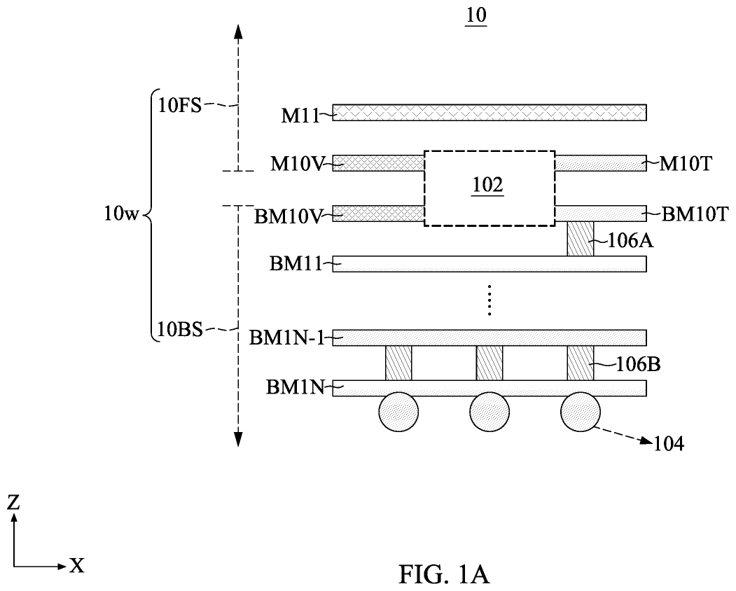

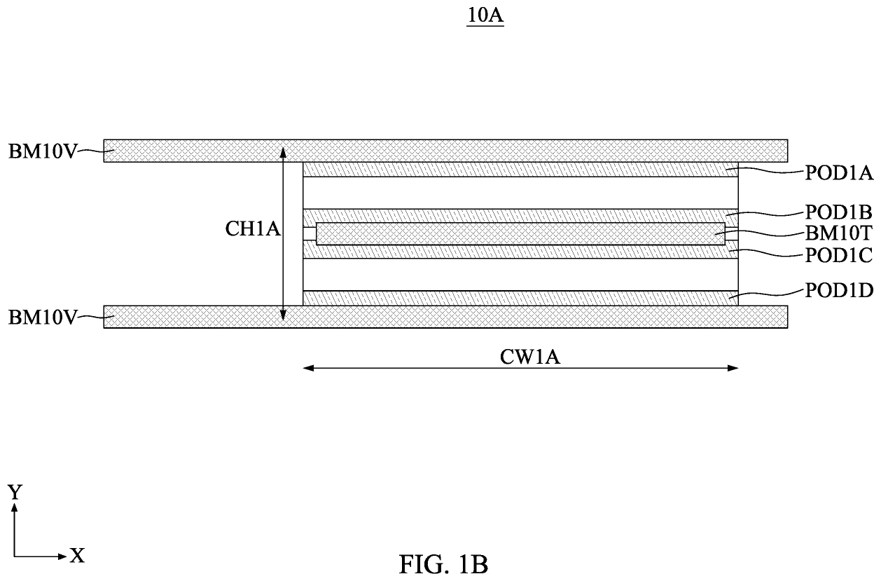

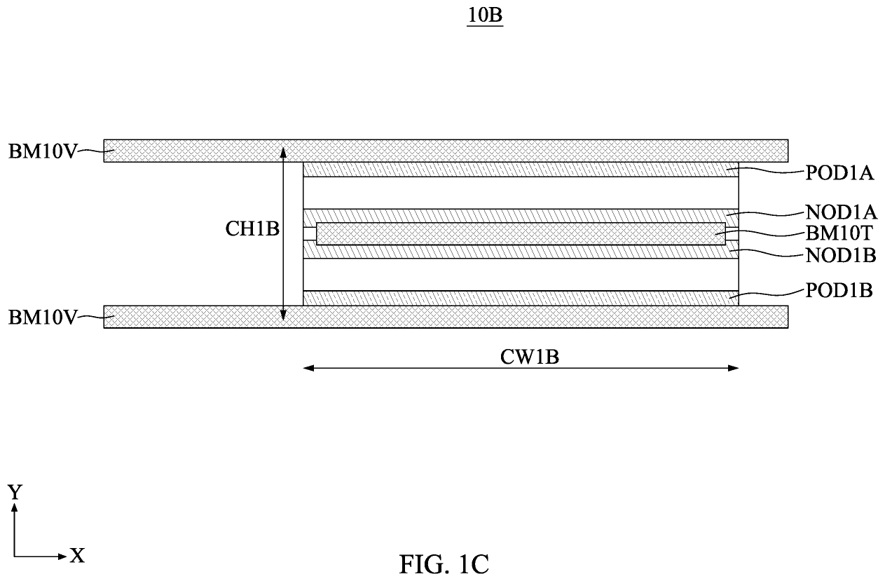

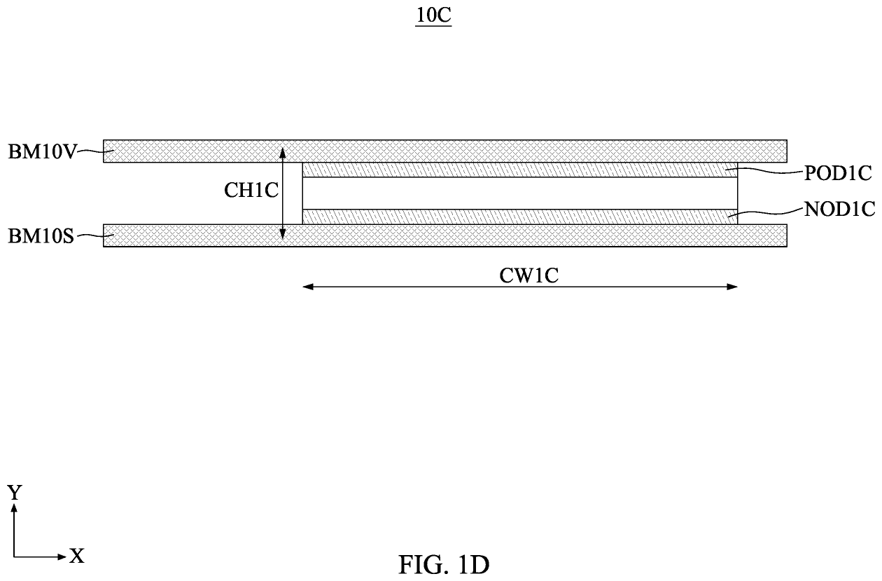

FIG. 1A is a schematic view of a semiconductor device 10 on a wafer 10w, in accordance with some embodiments of the present disclosure. The semiconductor device 10 can include, for example, an N-type metal-oxide-semiconductor (NMOS) device, a P-type metal-oxide-semiconductor (PMOS) device, a complementary metal-oxide-semiconductor (CMOS) device, and can be implemented using a planar field-effect transistor (FET) device, a fin-type FET (FinFET) device, a gate-all-around (GAA) device, a nanowire device, a fully-depleted silicon-on-isolator (FDSOI) device, or the like. The wafer 10w includes a semiconductor substrate and optionally various layers formed thereon.

Referring to FIG. 1A, the semiconductor device 10 includes a header cell 102, multiple conductive contacts 104 for receiving power supplies and multiple metal structures M11 to BM1N each extending along the X direction substantially parallel with each other. The header cell 102 spans the front side 10FS and the back side 10BS of the wafer 10w. The front side 10FS is opposite to the back side 10BS. The conductive contacts 104 can be electrically connected to a power source for providing power to the semiconductor device 10. In FIG. 1, the header cell 102 is represented by an empty dotted-box, without content therein. The details of the header cell 102 will be discussed later in accordance with FIGS. 1B, 1C, and 1D.

The metal structures M11 and M10, the latter of which includes two metal structures M10V and M10T, are formed on the front side 10FS of the wafer 10w. The metal structure M11 is formed above the header cell 102 and the metal structures M10V and M10T. The conductive contacts 104 and the metal structures BM10, BM11 to BM1N-1 and BM1N are formed on the back side 10BS of the wafer 10w. The metal structure BM10 includes two metal structures BM10V and BM10T separated by the header cell 102. The via structure 106A is formed between the metal structures BM10T and BM11. The via structures 106B are formed between the metal structures BM1N-1 and BM1N. The via structures 106A and 106B extend along the Z direction vertical to the X direction.

The header cell 102 can include a power switch cell to control power delivery of the semiconductor device 10. The technique of power gating may reduce power leakage when a system is not actively operating. The header cell 102 may provide a positive supply voltage VDD to other cells or elements of the semiconductor device 10. The metal structures M11 to BM1N, the conductive contacts 104, and the via structures 106A and 106B are made of metal, such as copper, aluminum, tungsten, titanium, tantalum, an alloy thereof or the like, and are electrically insulated by dielectric materials (not separately shown) such as oxide, nitride, oxynitride and the like.

In some embodiments, the metal structures M10V and BM10V belong to a virtual power domain. The virtual power domain is configured to transmit power from the header cell 102 to a standard cell or a functional cell which includes various kinds of logic gates or electronic elements. In some embodiments, the metal structures M10T, BM10T, BM11 to BM1N-1 and BM1N belong to a true power domain. The true power domain is configured to transmit power from a power supply or a power source to the header cell 102. The semiconductor device 10 can belong to a super power rail (SPR) chip design which includes or provides a power delivery network through the front side 10FS and the back side 10BS of the wafer 10w.

FIG. 1B is a schematic view of a design layout of the semiconductor device 10A, in accordance with some embodiments of the present disclosure. The semiconductor device 10A of FIG. 1B can correspond to a top view of the header cell 102 of the semiconductor device 10 of FIG. 1A.

The semiconductor device 10A includes several metal structures BM10V and BM10T extending along the X direction. The semiconductor device 10A includes multiple conductive structures POD1A, POD1B, POD1C and POD1D extending along the X direction. The conductive structures POD1A to POD1D can include a P-type active region, also referred to herein as oxide-diffusion (“OD”) regions. The active region may be used to form source/drain regions and a channel region between the source/drain regions of a transistor device. The semiconductor device 10A includes multiple PMOS devices without NMOS devices to reduce turn-on resistance.

The metal structures BM10T can partially overlap with the conductive structures POD1B and POD1C from a top-view perspective of the design layout. The header cell height CH1A can be defined as the distance between the two metal structures BM10V. The header cell width CW1A can be defined as the length of the conductive structures POD1A to POD1D along the X direction. In some embodiments, the header cell height CH1A can be twice the standard cell height, which is determined as the distance between two successive conductive structures, such as the conductive structures POD1A and POD1B. The header cell width CW1A can be greater than the header cell height CH1A.

FIG. 1C is a schematic view of a design layout of the semiconductor device 10B, in accordance with some embodiments of the present disclosure. The semiconductor device 10B of FIG. 1C can correspond to a top view of the header cell 102 of the semiconductor device 10 of FIG. 1A. The semiconductor device 10B of FIG. 1C can be similar to the semiconductor device 10A of FIG. 1B. The semiconductor device 10B has a header cell height CH1B and a header cell width CW1B.

In some embodiments, the semiconductor device 10B includes multiple PMOS devices and NMOS devices. The semiconductor device 10B includes conductive structures POD1A and POD1B. The semiconductor device 10B includes conductive structures NOD1A and NOD1B. The conductive structures POD1A and POD1B can be P-type, which means including a P-type active region. The conductive structures NOD1A and NOD1B can be N-type, which means including a N-type active region. The metal structures BM10T can partially overlap with the conductive structures NOD1A and NOD1B from a top-view perspective of the design layout.

FIG. 1D is a schematic view of a design layout of the semiconductor device 10C, in accordance with some embodiments of the present disclosure. The semiconductor device 10C can correspond to a portion of a functional cell or a standard cell. The semiconductor device 10C has a cell height CH1C and a cell width CW1C.

In some embodiments, the semiconductor device 10C includes multiple PMOS devices and NMOS devices. The semiconductor device 10C includes conductive structures POD1C and NOD1C. The conductive structure POD1C can include a P-type active region. The conductive structures NOD1C can include an N-type active region. The cell width CW1C can be substantially identical to the header cell widths CW1A and CW1B. The cell height CH1C can be smaller than the header cell heights CH1A and CH1B. The cell height CH1C can be substantially half of the header cell heights CH1A and CH1B.

In some embodiments, the header cell of the semiconductor device 10A of FIG. 1B including PMOS device is exclusive to or not compatible with the standard cell of the semiconductor device 10C of FIG. 1D including both PMOS device and NMOS device. In some embodiments, the header cell of the semiconductor device 10B of FIG. 1C including both PMOS device and NMOS device is compatible with the standard cell of the semiconductor device 10C of FIG. 1D including both PMOS device and NMOS device. The header cell of the semiconductor device 10B of FIG. 1C shares the same configuration of both PMOS device and NMOS device as the standard cell of the semiconductor device 10C of FIG. 1D. Therefore, the header cell of the semiconductor device 10B of FIG. 1C provides an advantage of higher capacity of integrating with other standard cells on the same chip.

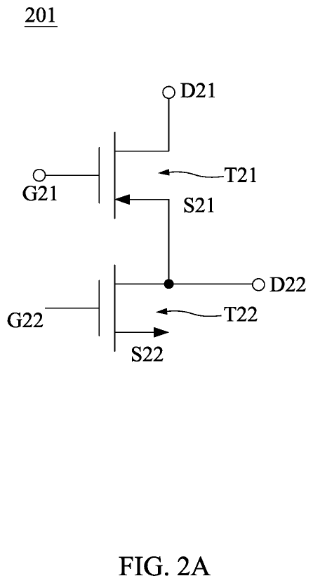

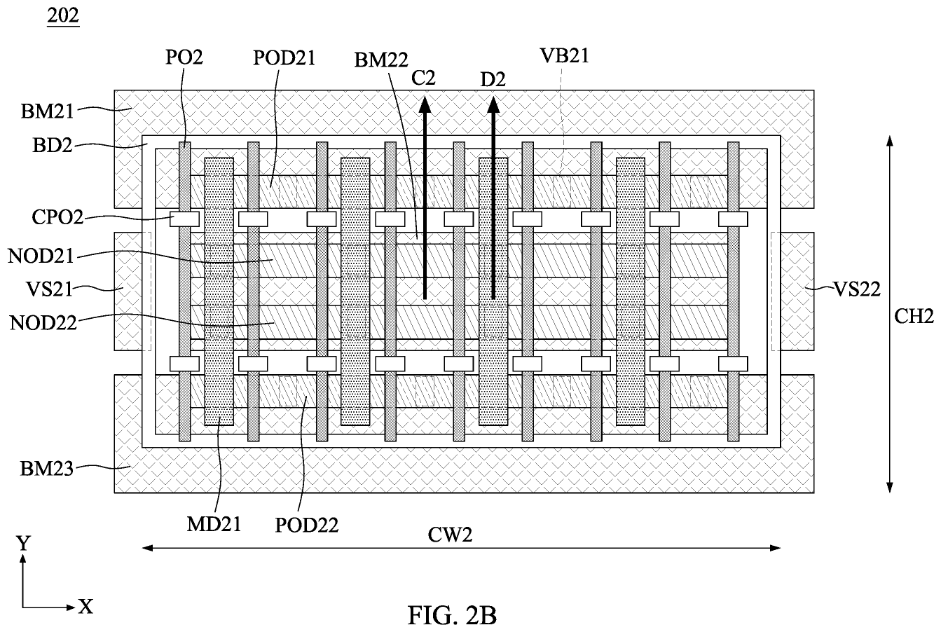

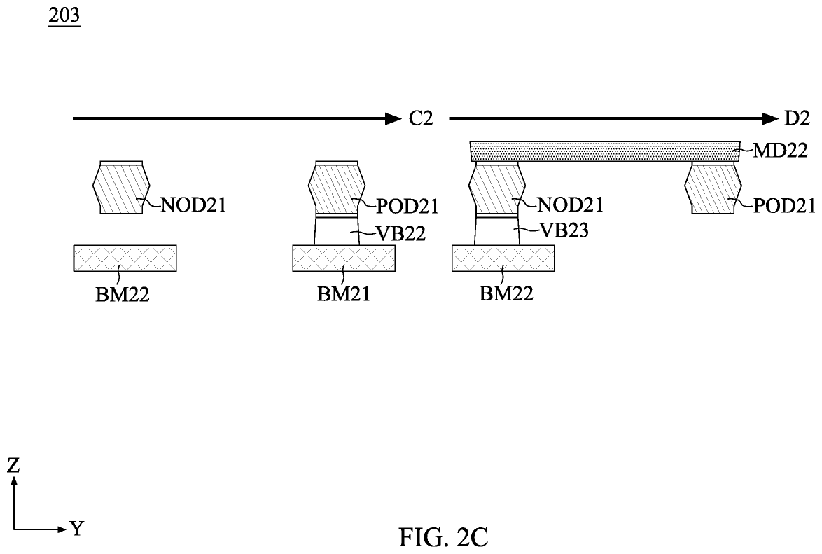

FIG. 2A is a schematic diagram of a semiconductor device 201, in accordance with some embodiments of the present disclosure. The semiconductor device 201 can correspond to the header cell as illustrated in the embodiments of FIG. 1A and FIG. 1C.

The semiconductor device 201 includes a PMOS transistor T21 and an NMOS transistor T22. The PMOS transistor T21 includes drain D21, gate G21 and source S21. The NMOS transistor T22 includes drain D22, gate G22 and source S22. A source/drain region(s) may refer to a source or a drain, individually or collectively depending upon the context. In some embodiments, the gate G21 can be used to receive a control signal. The gate G22 and source S22 are floating without being electrically connected to other signals and elements. The NMOS transistor T22 can be used as a dummy transistor for providing a signal path or a current path between drain D22 and source S21.

FIG. 2B is a schematic diagram of a design layout of a semiconductor device 202, in accordance with some embodiments of the present disclosure. The semiconductor device 202 of FIG. 2B can correspond to the semiconductor device 201 of FIG. 2A.

The semiconductor device 202 includes several metal structures BM21, BM22 and BM23, several conductive structures POD21, NOD21, NOD22 and POD22, several gates PO2, several via structures VB21, several metal layer structures MD21, and several isolating structures CPO2. The conductive structures POD21 to NOD22, the gates PO1, the metal layer structures MD21, and the isolating structures CPO2 are formed within the boundary BD2. The isolating structures CPO2 are used to avoid short-circuiting so that the conductive structure POD21 is void of electrically connected to the conductive structure NOD21. The voltage structures VS21 and VS22 are formed outside the boundary BD2. The voltage structures VS21 and VS22 are spaced apart from the metal structure BM22. The metal structure BM21 can be electrically connected to the drain D21 of the PMOS transistor T21 of FIG. 2A. The metal structure BM22 can be electrically connected to the drain D22 of the NMOS transistor T22 of FIG. 2A. The voltage structures VS21 and VS22 can be grounded or electrically connected to a voltage source VSS.

As shown in FIG. 2B, the metal structures BM21, BM22 and BM23 extend along the X direction. The metal structure BM21 is spaced apart or separated from the metal structure BM22 along the Y direction. The metal structure BM22 is spaced apart or separated from the metal structure BM23 along the Y direction. The conductive structures POD21, NOD21, NOD22 and POD22 extend along the X direction. The gates PO2 extend along the Y direction. The metal layer structures MD21 extend along the Y direction. The conductive structures POD21 and POD22 are P-type active regions, and the conductive structures NOD21 and NOD22 are N-type active regions. The metal layer structures MD21 can have material similar to that of the metal structures BM21 to BM23.

In some embodiments, the metal structures BM21 and BM23 belong to a true power domain. The metal structure BM22 belongs to virtual power domain. In some embodiments, the conductive structure POD21 overlaps with the metal structure BM21 from a top-view perspective of the design layout. The conductive structure POD22 overlaps with the metal structure BM23 from a top-view perspective of the design layout. The conductive structures NOD21 and NOD22 partially overlap with the metal structure BM22 from a top-view perspective of the design layout. The conductive structures NOD21 and NOD22 are within the metal structure BM22 from a top-view perspective of the design layout.

The semiconductor device 202 has a header cell height CH2 along the Y direction and a header cell width CW2 along the X direction. The header cell height CH2 can be twice the standard cell height, which is determined as the distance between two successive conductive structures, such as the conductive structures POD21 and NOD21. The header cell width CW2 can be in a range of 3 to 256 pitches, and the pitch is defined as the distance between two successive gates PO2. The width of the metal structure BM22 along the Y direction is greater than the width of the conductive structures NOD21 and NOD22 along the Y direction. The width of the metal structure BM22 along the Y direction is greater than twice the width of the conductive structures NOD21 and NOD22 along the Y direction.

FIG. 2C illustrates cross-section views of the semiconductor device 203 along the section lines C2 and D2 in FIG. 2B, in accordance with some embodiments of the present disclosure. The semiconductor device 203 of FIG. 2C can correspond to a portion of the semiconductor device 202 of FIG. 2B.

Referring to FIG. 2C, along the section line C2, the conductive structure NOD21 is formed above the metal structure BM22 along the Z direction. The via structure VB22 is formed on the metal structure BM21 along the Z direction, and the conductive structure POD21 is formed on the via structure VB22 along the Z direction. The conductive structure POD21 can be in direct contact with the via structure VB22, and a hetero-junction interface can be formed therebetween.

In some embodiments, along the section line D2, the via structure VB23 is formed on the metal structure BM22 along the Z direction. The conductive structure NOD21 is formed on the via structure VB23 along the Z direction. The conductive structure NOD21 can be in direct contact with the via structure VB23, and a hetero-junction interface can be formed therebetween. The metal layer structure MD21 is formed on the conductive structures NOD21 and POD21 along the Z direction. The metal layer structure MD21 can be in direct contact with the conductive structures NOD21 and POD21. In some embodiments, the metal structures BM21 and BM22 are formed on the back side of the wafer. The conductive structures NOD21 and POD21 are formed on the front side of the wafer. The metal layer structure MD22 is formed on the front side of the wafer. In some embodiments, a path can be provided to electrically connect the metal structure BM22 (corresponding to the drain D22) to the source S21 through the via structure VB23, the conductive structure NOD21 and the metal layer structure MD22.

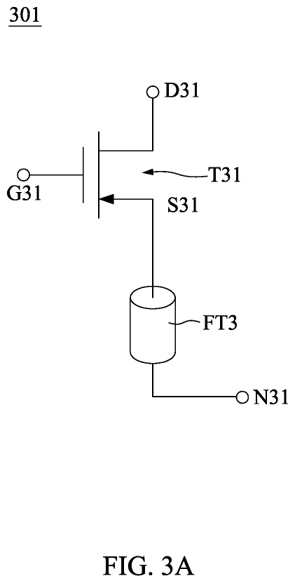

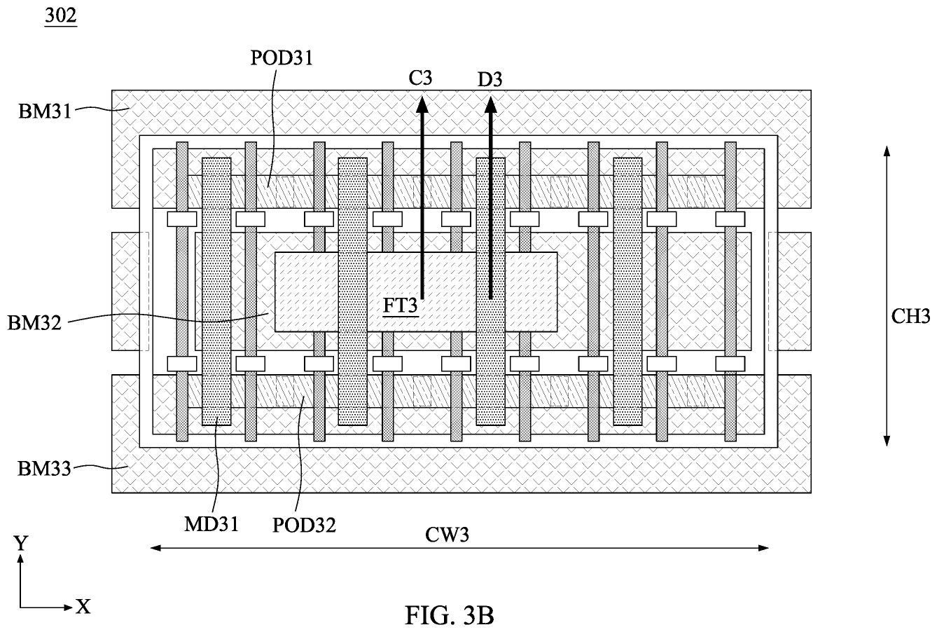

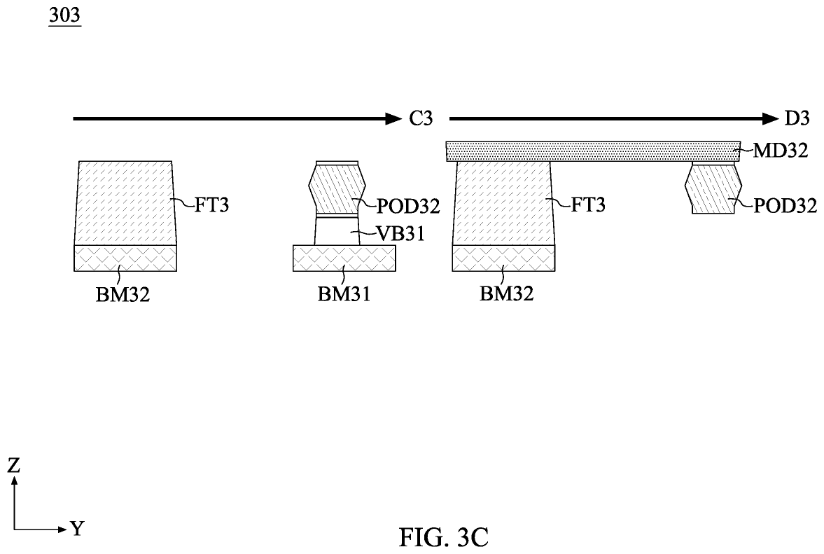

FIG. 3A is a schematic diagram of a semiconductor device 301, in accordance with some embodiments of the present disclosure. The semiconductor device 301 of FIG. 3A can be similar to the semiconductor device 201 of FIG. 2A.

The semiconductor device 301 includes a through via structure FT3 and a PMOS transistor T31 with gate G31, drain D31 and source S31. The through via structure FT3 is electrically connected between the source S31 and the node N31. The through via structure FT3 is used to replace NMOS transistor T22 of FIG. 2A to decrease the turn-on resistance of the semiconductor device 301. The through via structure FT3 is made of metal, such as copper, aluminum, tungsten, titanium, tantalum, an alloy thereof or the like, and is electrically insulated by dielectric materials (not separately shown) such as oxide, nitride, oxynitride and the like.

FIG. 3B is a schematic diagram of a design layout of a semiconductor device 302, in accordance with some embodiments of the present disclosure. The semiconductor device 302 of FIG. 3B can correspond to the semiconductor device 301 of FIG. 3A. The metal structure BM31 can be electrically connected to the drain D31 of FIG. 3A. The metal structure BM32 can be electrically connected to the node N31 of FIG. 3A.

The semiconductor device 302 includes the metal structures BM31, BM32 and BM33 along the X direction, the conductive structures POD31 and POD32 along the X direction, several metal layer structures MD31 along the Y direction, and a through via structure FT3 extending along the X direction. The semiconductor device 302 has a header cell height CH3 and a header cell width CW3. The metal structures BM31 and BM33 belong to a virtual power domain. The metal structure BM32 belongs to a true power domain.

In some embodiments, the through via structure FT3 overlaps a portion of the metal structure BM32 from a top-view perspective of the design layout. The through via structure FT3 is formed within the metal structure BM32 from a top-view perspective of the design layout. The length of the through via structure FT3 along the X direction is smaller than the length of the metal structure BM32 along the X direction. The width of the through via structure FT3 along the Y direction is smaller than the width of the metal structure BM32 along the Y direction.

FIG. 3C illustrates cross-section views of a semiconductor device 303 along the section lines C3 and D3 in FIG. 3B, in accordance with some embodiments of the present disclosure. The semiconductor device 303 of FIG. 3C can correspond to a portion of the semiconductor device 302 of FIG. 3B and can be similar to the semiconductor device 203 of FIG. 2C.

Along the section line C3, the through via structure FT3 is formed on the metal structure BM32 along the Z direction. The conductive structure POD32 and the via structure VB31 are formed on the metal structure BM31 along the Z direction. Along the section line D3, the through via structure FT3 is formed on the metal structure BM32 along the Z direction. The metal layer structure MB32 is formed on the through via structure FT3 and the conductive structure POD32. The through via structure FT3 is formed between the metal structure BM23 and the metal layer structure MD32. In some embodiments, the size of the through via structure FT3 is greater than the size of the via structure VB31 to reduce the resistance. The metal structures BM31 and BM32 are formed on the back side of the wafer. The through via structure FT3 can be formed on the front side of the wafer.

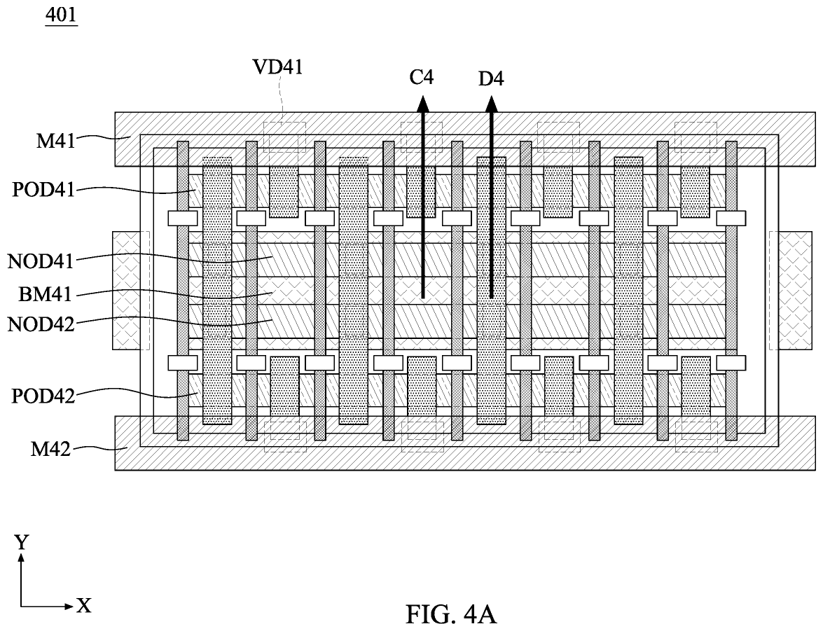

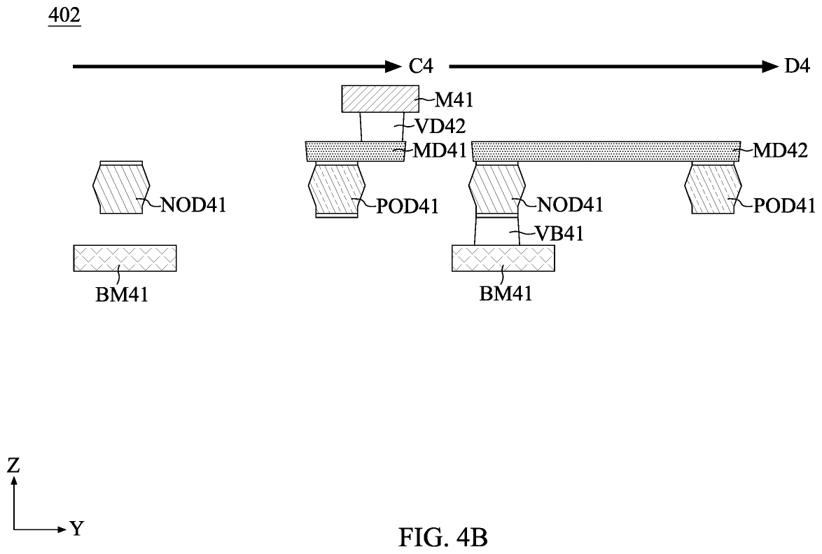

FIG. 4A is a schematic diagram of a design layout of a semiconductor device 401, in accordance with some embodiments of the present disclosure. The semiconductor device 401 of FIG. 4A can be similar to the semiconductor device 202 of FIG. 2B and correspond to the semiconductor device 201 of FIG. 2A.

Referring to FIG. 4A, the semiconductor device 401 includes the metal structures M41, M42 and BM41 along the X direction, the conductive structures POD41, POD42, NOD41 and NOD42 along the X direction, and multiple via structures VD41. The metal structures M41 and M42 belong to a virtual power domain. The metal structure BM41 belongs to a true power domain.

In some embodiments, the conductive structures NOD41 and NOD42 overlap a portion of the metal structure BM41 from a top-view perspective of the design layout. The conductive structures NOD41 and NOD42 are formed within the metal structure BM41 from a top-view perspective of the design layout. The width of the conductive structures NOD41 and NOD42 along the Y direction is smaller than the width of the metal structure BM41 along the Y direction. The width of the metal structure BM41 along the Y direction is greater than twice the width of the conductive structures NOD41 and NOD42 along the Y direction.

In some embodiments, the width of the conductive structures POD41 and POD42 along the Y direction is smaller than the width of the metal structures M41 and M42 along the Y direction. The conductive structure POD41 is formed between and spaced apart from the metal structures M41 and BM41. The conductive structure POD42 is formed between and spaced apart from the metal structures M42 and BM41.

FIG. 4B illustrates cross-section views of a semiconductor device 402 along the section lines C4 and D4 in FIG. 4A, in accordance with some embodiments of the present disclosure. The semiconductor device 402 of FIG. 4B can be similar to the semiconductor device 203 of FIG. 2C and correspond to a portion of the semiconductor device 201 of FIG. 2A.

Along the section line C4, the metal layer structure MD41 is formed on the conductive structure POD41 along the Z direction. The via structure VD42 is formed between the metal structure M41 and the metal layer structure MD41. Along the section line D4, the metal layer structure MD42 is formed on the conductive structures NOD41 and POD41 along the Z direction. The metal structures BM41 and BM42 are formed on the back side of the wafer. The POD41, POD42, NOD41 and NOD42 are formed on the front side of the wafer. The metal structure M41 is formed on the front side of the wafer.

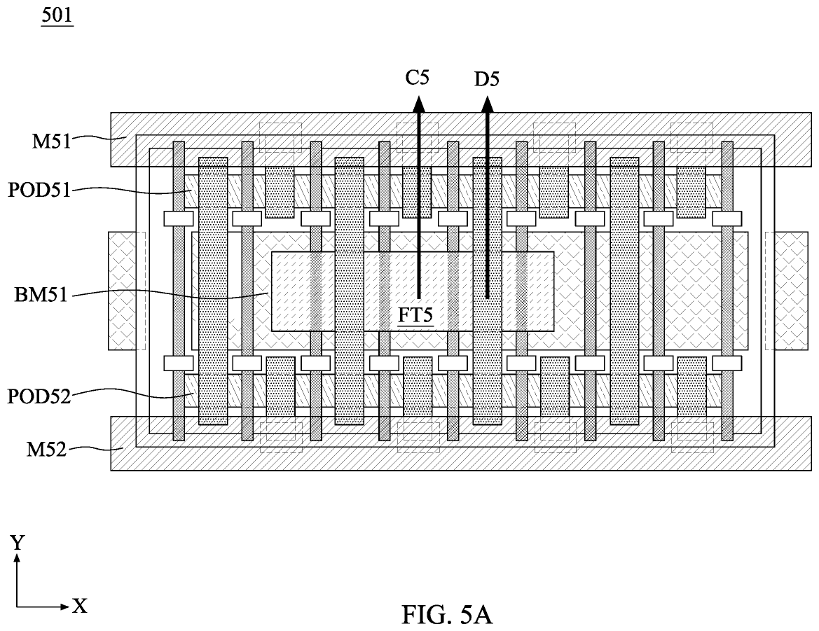

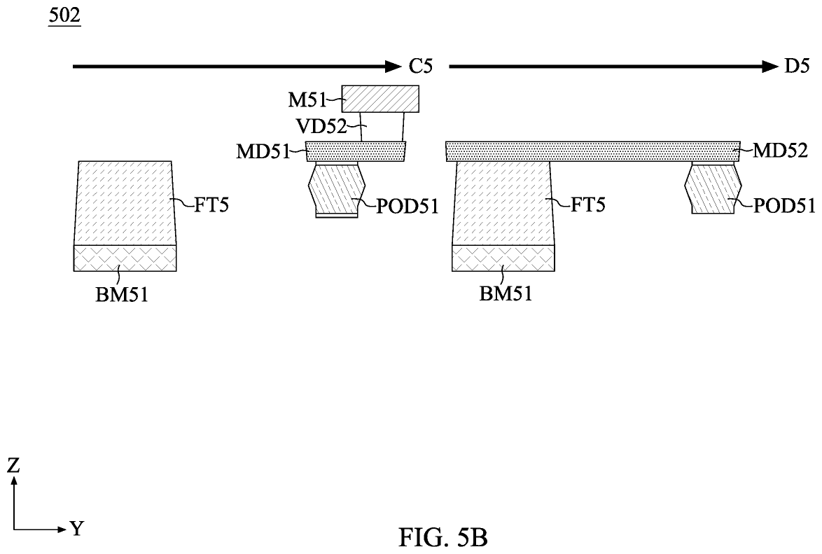

FIG. 5A is a schematic diagram of a design layout of a semiconductor device 501, in accordance with some embodiments of the present disclosure. The semiconductor device 501 of FIG. 5A can be similar to the semiconductor device 302 of FIG. 3B and the semiconductor device 401 of FIG. 4A, and correspond to the semiconductor device 301 of FIG. 3A.

The semiconductor device 501 includes the metal structures M51, M52 and BM51 along the X direction, the conductive structures POD51 and POD52 along the X direction, and the through via structure FT5 extending along the X direction. The metal structures M51 and M52 belong to a virtual power domain. The metal structure BM51 belongs to a true power domain.

FIG. 5B illustrates cross-section views of a semiconductor device 502 along the section lines C5 and D5 in FIG. 5A, in accordance with some embodiments of the present disclosure. The semiconductor device 502 of FIG. 5B can be similar to the semiconductor device 303 of FIG. 3C and the semiconductor device 402 of FIG. 4B.

Along the section line C5, the through via structure FT5 is formed on the metal structure BM51 along the Z direction. The metal layer structure MD51 is formed on the conductive structure POD51 along the Z direction. The via structure VD52 is formed between the metal structure M51 and the metal layer structure MD51. Along the section line D5, the metal layer structure MD52 is formed on the conductive structures POD51 and the through via structure FT5 along the Z direction. The metal structures BM51 and BM52 are formed on the back side of the wafer. The conductive structure POD51 and the through via structure FT5 are formed on the front side of the wafer. The metal structure M51 is formed on the front side of the wafer.

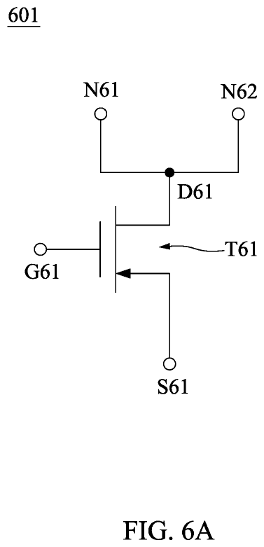

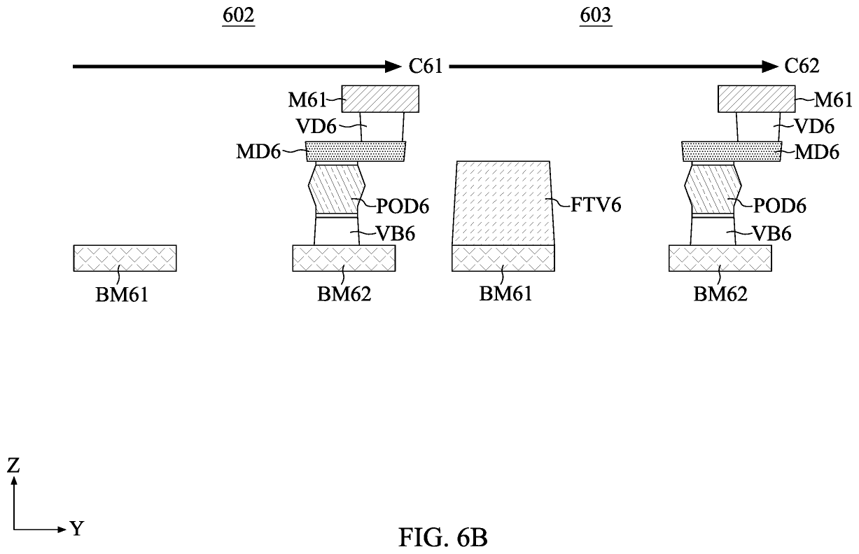

FIG. 6A is a schematic diagram of a semiconductor device 601, in accordance with some embodiments of the present disclosure. The semiconductor device 601 of FIG. 6A can be similar to the semiconductor device 201 of FIG. 2A. The semiconductor device 601 includes a PMOS transistor T61 including gate G61, drain D61 and source S61. The drain D61 is electrically connected to two nodes N61 and N62.

FIG. 6B illustrates cross-section views of two semiconductor devices 602 and 603 along the section lines C61 and C62, in accordance with some embodiments of the present disclosure. The embodiment of the section line C61 can correspond to both embodiments of the section line C2 in FIG. 2C and the section line C4 in FIG. 4B. The embodiment of the section line C62 can correspond to both embodiments of the section line C3 in FIG. 3C and the section line C5 in FIG. 5B.

Along the section line C61, the metal structure BM61 can be electrically connected to the source S61 of FIG. 6A. The metal structure BM62 can be electrically connected to the node N61 of FIG. 6A. The metal structure M61 can be electrically connected to the node N62 of FIG. 6A. The metal structures BM61 and BM61 are formed on the back side of the wafer. The conductive structure POD6, the metal layer structure MD6, the via structures VB6 and VD6 and the metal structure M61 are formed on the front side of the wafer.

Along the section line C62, the metal structure BM61 can be electrically connected to the source S61 of FIG. 6A. The metal structure BM62 can be electrically connected to the node N61 of FIG. 6A. The metal structure M61 can be electrically connected to the node N62 of FIG. 6A. The metal structures BM61 and BM61 are formed on the back side of the wafer. The through via structure FTV6, the conductive structure POD6, the metal layer structure MD6, the via structures VB6 and VD6 and the metal structure M61 are formed on the front side of the wafer.

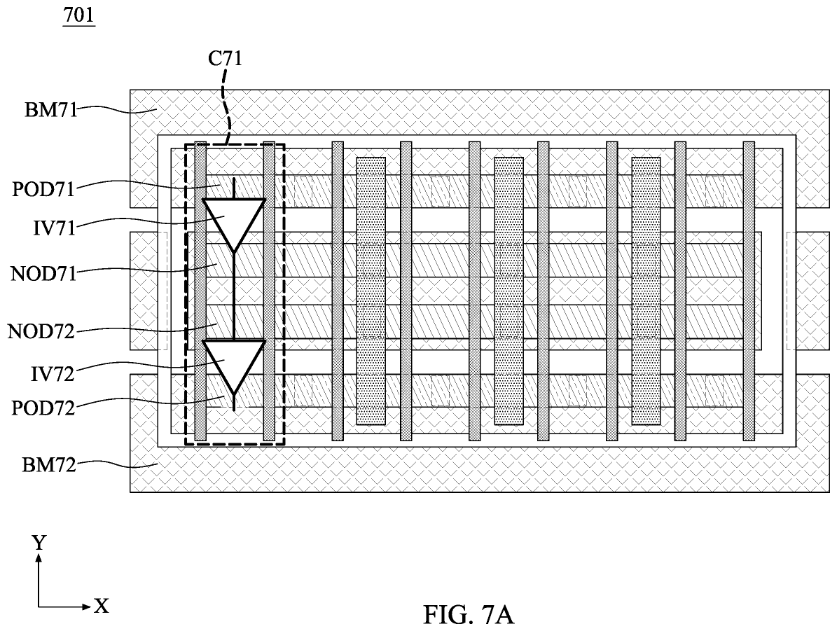

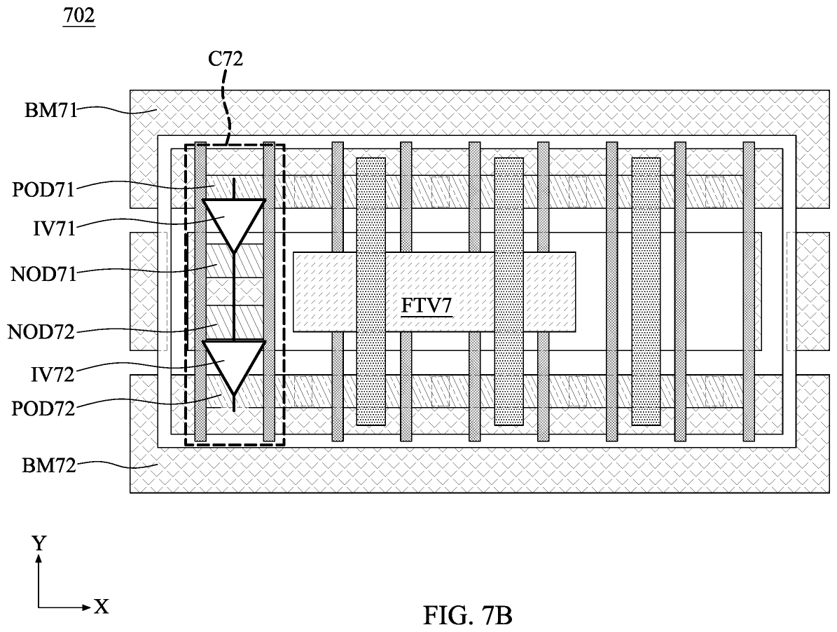

FIG. 7A is a schematic diagram of a design layout of a semiconductor device 701, in accordance with some embodiments of the present disclosure. The semiconductor device 701 of FIG. 7A can be similar to the semiconductor device 202 of FIG. 2B.

The semiconductor device 701 includes several metal structures BM71 and BM71, several conductive structures POD71, NOD71, NOD72 and POD72, and a control circuit C71. The control circuit C71 can include an inverter chain or a buffer chain to control the turn-on and turn-off of the semiconductor device 701 including or correspond to a header cell. The control circuit C71 includes two inverters IV71 and IV72. Each of the inverters IV71 and IV72 can include a NMOS transistor and a PMOS transistor. The inverters IV71 and IV72 can be used to generate the control signal to the gate, such as the gate G21 in FIG. 2A. The control circuit C71 is built-in or embedded within the header cell of the semiconductor device 701.

FIG. 7B is a schematic diagram of a design layout of another semiconductor device 702, in accordance with some embodiments of the present disclosure. The semiconductor device 702 of FIG. 7B can be similar to the semiconductor device 302 of FIG. 3B and the semiconductor device 701 of FIG. 7A. The semiconductor device 701 includes a control circuit C72 and a through via structure FTV7. The control circuit C72 can include an inverter chain or a buffer chain to control the turn-on and turn-off of the semiconductor device 702 as a header cell. The control circuit C72 includes two inverters IV71 and IV72. Each of the inverters IV71 and IV72 can include a NMOS transistor and a PMOS transistor. The inverters IV71 and IV72 can be used to generate the control signal to the gate, such as the gate G21 in FIG. 2A. The control circuit C72 is built-in or embedded within the header cell of the semiconductor device 702.

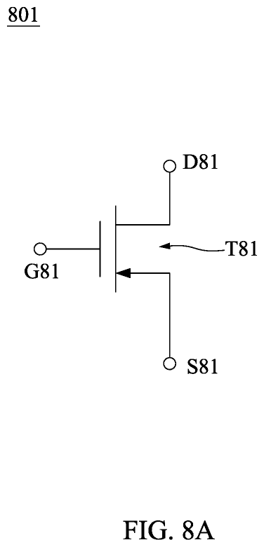

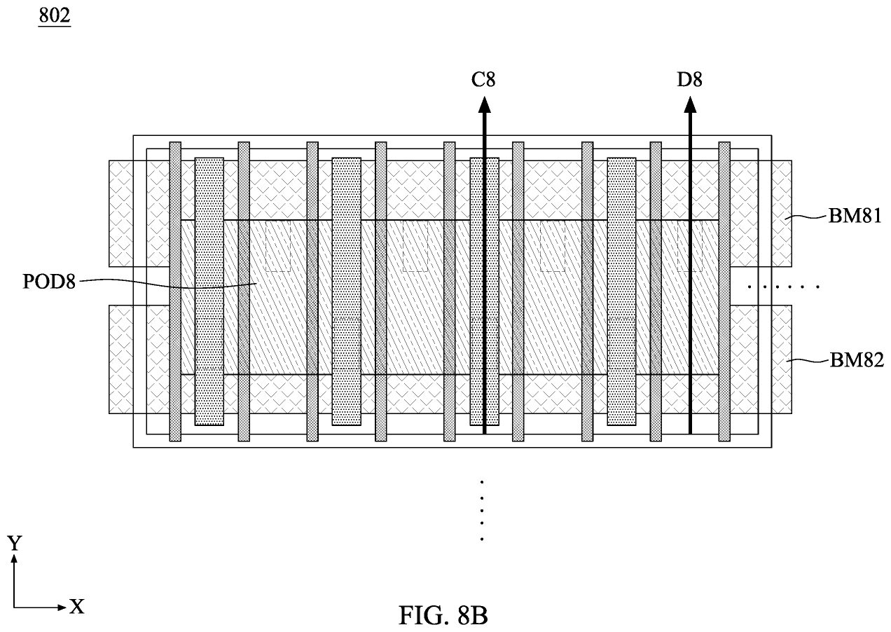

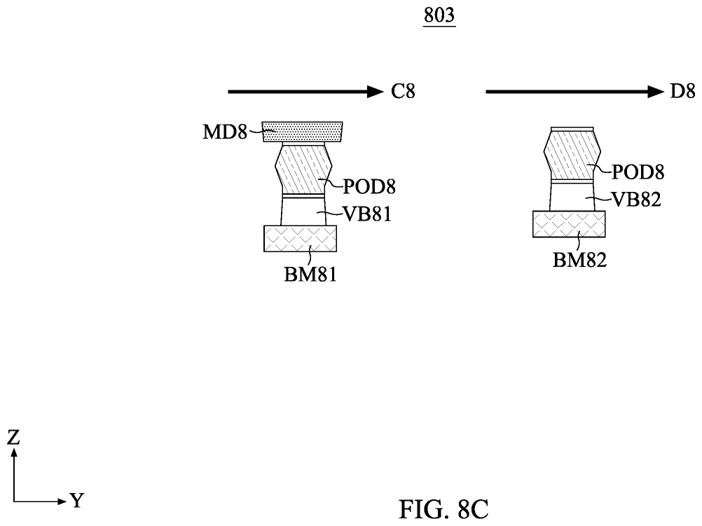

FIG. 8A is a schematic diagram of a semiconductor device 801, in accordance with some embodiments of the present disclosure. The semiconductor device 801 can correspond to or belong to a portion of the header cell. The semiconductor device 801 includes a PMOS transistor T81. The semiconductor device 801 is void of NMOS transistors. The PMOS transistor T81 includes drain D81, gate G81 and source S81. The gate G81 is used to receive a control signal.

FIG. 8B is a schematic diagram of a design layout of a semiconductor device 802, in accordance with some embodiments of the present disclosure. The semiconductor device 802 can correspond to the semiconductor device 801 of FIG. 8A or be similar to the semiconductor device 202 of FIG. 2B.

The semiconductor device 802 includes two metal structures BM81 and BM82 extending along the X direction, and a conductive structure POD8 extending along the Y direction. The metal structure BM82 is electrically connected to drain D81 of FIG. 8A. The metal structure BM81 is electrically connected to source S81 of FIG. 8A. The conductive structure POD8 partially overlaps the metal structure BM81 from a top-view perspective of the design layout. The conductive structure POD8 partially overlaps the metal structure BM82 from a top-view perspective of the design layout. The metal structure BM81 belongs to a true power domain. The metal structure BM82 belongs to a virtual power domain.

The header cell of the semiconductor device 802 can have more flexibility than a standard cell and have more additional layout structures. The header cell of the semiconductor device 802 can be used, for example, as a static random-access memory (SRAM) circuit or an input-output (I/O) circuit. The widths of the metal structures BM81 and BM82 along the Y direction can be increased to enhance the IR drop, which is proportional to resistance. In addition, NMOS transistors is unnecessary for the header cell of the semiconductor device 802.

FIG. 8C illustrates cross-section views of a semiconductor device 803 along the section lines C8 and D8 in FIG. 8B, in accordance with some embodiments of the present disclosure. The semiconductor device 803 can correspond to the semiconductor device 802 of FIG. 8B.

Along the section line C8, the metal layer structure MD8, the conductive structure POD8 and the via structure VB81 are formed on the metal structure BM81 along the Z direction. The metal structure BM81 is formed on the back side of the wafer. The metal layer structure MD8, the conductive structure POD8 and the via structure VB81 are formed on the front side of the wafer. The conductive structure POD8 include P-type active regions. Along the section line D8, the conductive structure POD8 and the via structure VB82 are formed on the metal structure BM82 along the Z direction. The metal structure BM82 is formed on the back side of the wafer. The conductive structure POD8 and the via structure VB82 are formed on the front side of the wafer.

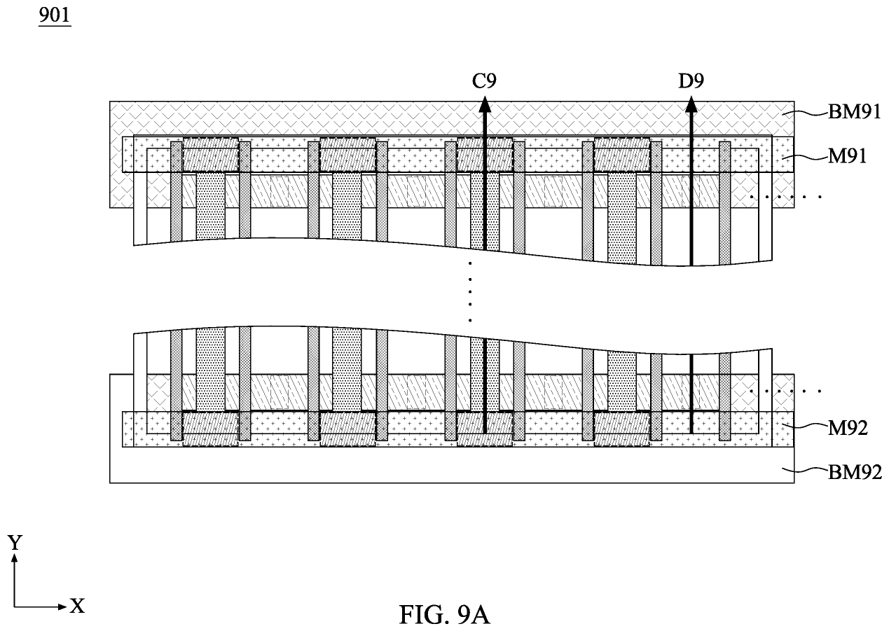

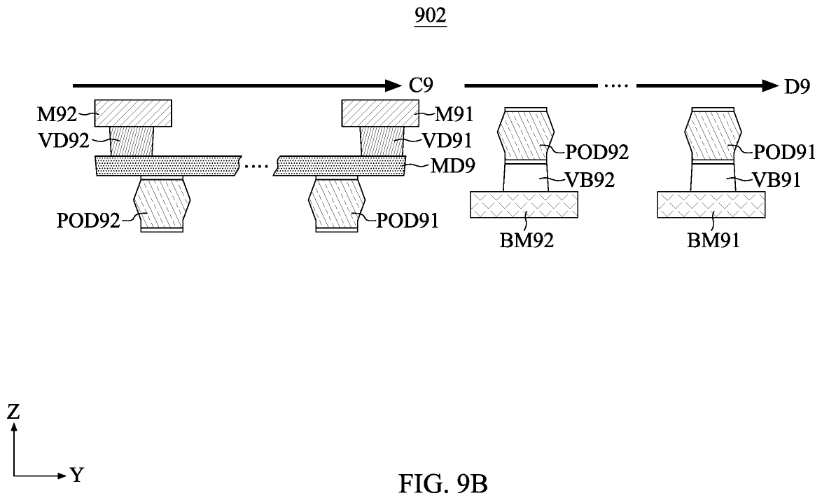

FIG. 9A is a schematic diagram of a design layout of a semiconductor device 901, in accordance with some embodiments of the present disclosure. The semiconductor device 901 can correspond to the semiconductor device 801 of FIG. 8A or be similar to the semiconductor device 802 of FIG. 8B. The semiconductor device 901 includes four metal structures M91, M92, BM91 and BM92 extending along the X direction. The metal structures M91 and M92 belong to a virtual power domain. The metal structures BM91 and BM92 belong to a true power domain. The metal structures M91 and M92 are electrically connected to drain D81 of FIG. 8A. The metal structures BM91 and BM92 are electrically connected to source S81 of FIG. 8A.

FIG. 9B illustrates cross-section views of a semiconductor device 902 along the section lines C9 and D9 in FIG. 9A, in accordance with some embodiments of the present disclosure. The semiconductor device 902 can correspond to the semiconductor device 901 of FIG. 9A.

Along the section line C9, the metal layer structure MD9 is formed on the conductive structures POD91 and POD92. The metal layer structure MD9 extends along the Y direction. The metal structure M92 and the via structure VD92 are formed on the metal layer structure MD9. The metal structure M91 and the via structure VD91 are formed on the metal layer structure MD9. The metal structures M91 and M92 are formed on the front side of the wafer. Along the section line D9, the conductive structure POD92 and the via structure VB92 are formed on the metal structure BM92. The conductive structure POD91 and the via structure VB91 are formed on the metal structure BM91. The metal structures BM91 and BM91 are formed on the back side of the wafer.

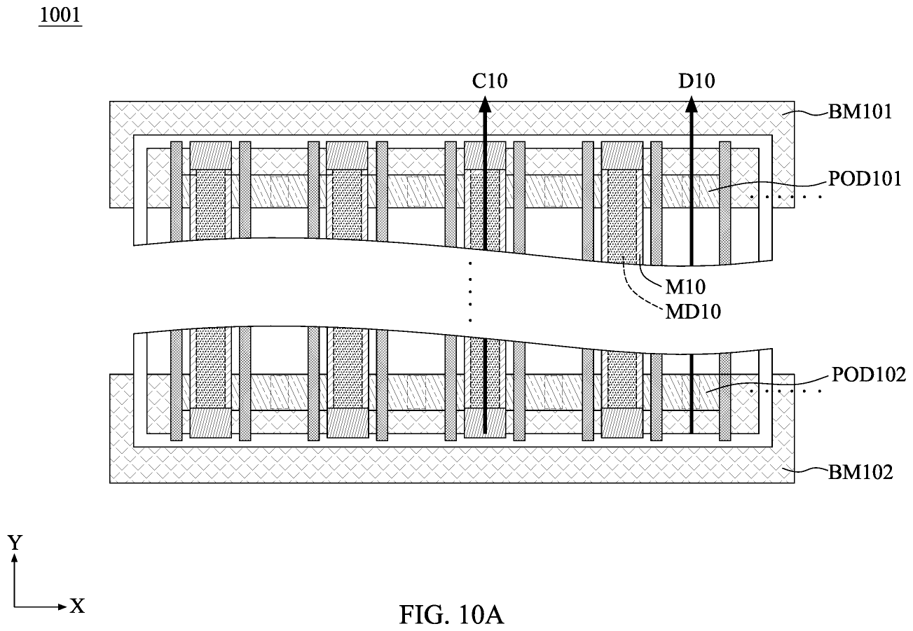

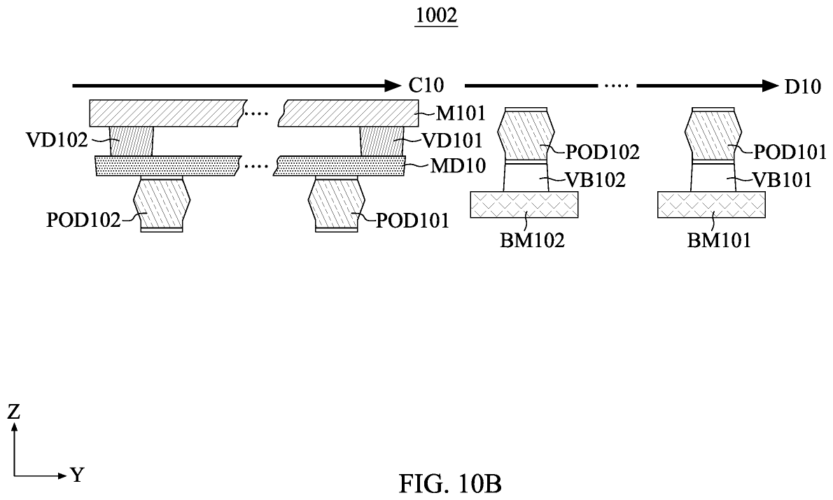

FIG. 10A is a schematic diagram of a design layout of a semiconductor device 1001, in accordance with some embodiments of the present disclosure. The semiconductor device 1001 can correspond to the semiconductor device 801 of FIG. 8A.

The semiconductor device 1001 includes two metal structures BM101 and BM102 extending along the X direction. The semiconductor device 1001 includes two conductive structures POD101 and POD102 that extend along the X direction and include P-type active regions. The semiconductor device 1001 includes a metal structure M10 extending along the Y direction. The semiconductor device 1001 includes a metal layer structure MD10 extending along the Y direction. The metal structure M10 belongs to virtual power domain. The metal structures BM101 and BM102 belong to a true power domain. The metal structure M10 is electrically connected to drain D81 of FIG. 8A. The metal structures BM101 and BM102 are electrically connected to source S81 of FIG. 8A.

FIG. 10B illustrates cross-section views of a semiconductor device 1002 along the section lines C10 and D10 in FIG. 10A, in accordance with some embodiments of the present disclosure. The semiconductor device 1002 can correspond to the semiconductor device 1001 of FIG. 10A.

Along the section line C10, the via structures VD101 and VD102 are formed between the metal structure M101 and the metal layer structure MD10. The metal layer structure MD10 is formed on the conductive structures POD101 and POD102. The metal structure M101, the via structures VD101 and VD102 and the metal layer structure MD10 can be formed on the front side of the wafer. Along the section line D10, the conductive structure POD102 and the via structure VB102 are formed on the metal structure BM102. The conductive structure POD101 and the via structure VB101 are formed on the metal structure BM101. The metal structures BM101 and BM102 are formed on the back side of the wafer.

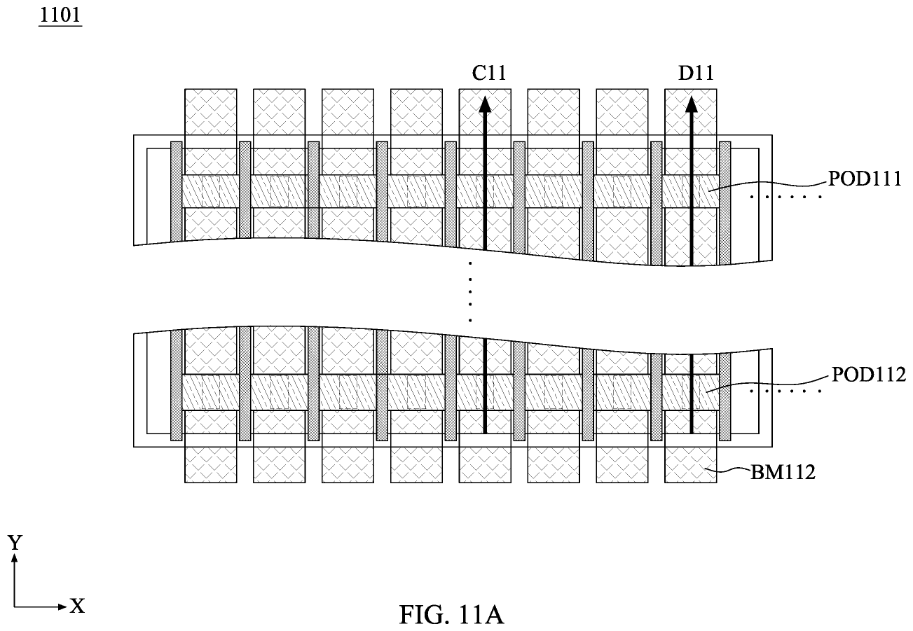

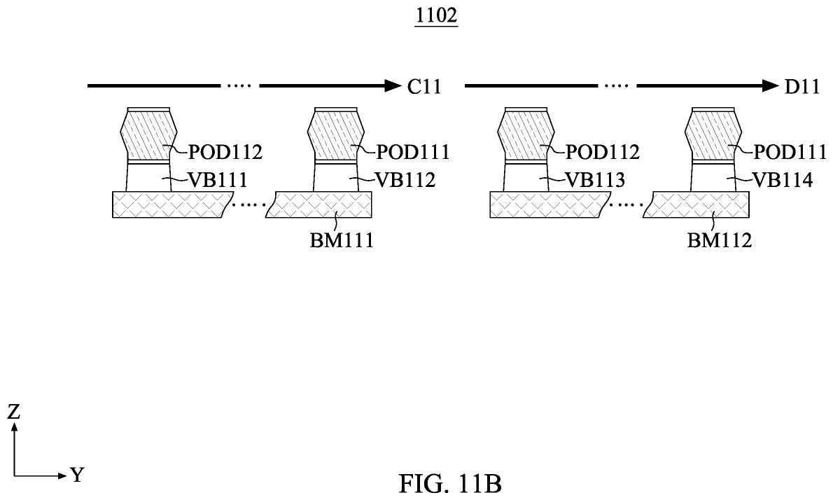

FIG. 11A is a schematic diagram of a design layout of a semiconductor device 1101, in accordance with some embodiments of the present disclosure. The semiconductor device 1101 can correspond to the semiconductor device 801 of FIG. 8A. The semiconductor device 1101 includes two conductive structures POD111 and POD112 that extend along the X direction and include P-type active regions. The semiconductor device 1001 includes a metal structure BM112 extending along the Y direction.

FIG. 11B illustrates cross-section views of a semiconductor device 1102 along the section lines C11 and D11 in FIG. 11A, in accordance with some embodiments of the present disclosure. The semiconductor device 1102 can correspond to the semiconductor device 1101 of FIG. 11A.

Along the section line C11, the conductive structures POD111 and POD112, and the via structures VB111 and VB112 are formed on the metal structure BM111. Along the section line D11, the conductive structures POD111 and POD112, and the via structures VB113 and VB114 are formed on the metal structure BM112. The metal structures BM111 and BM112 are formed on the back side of the wafer. The metal structure BM111 is electrically connected to the source S81 of FIG. 8A. The metal structure BM112 is electrically connected to the drain D81 of FIG. 8A.

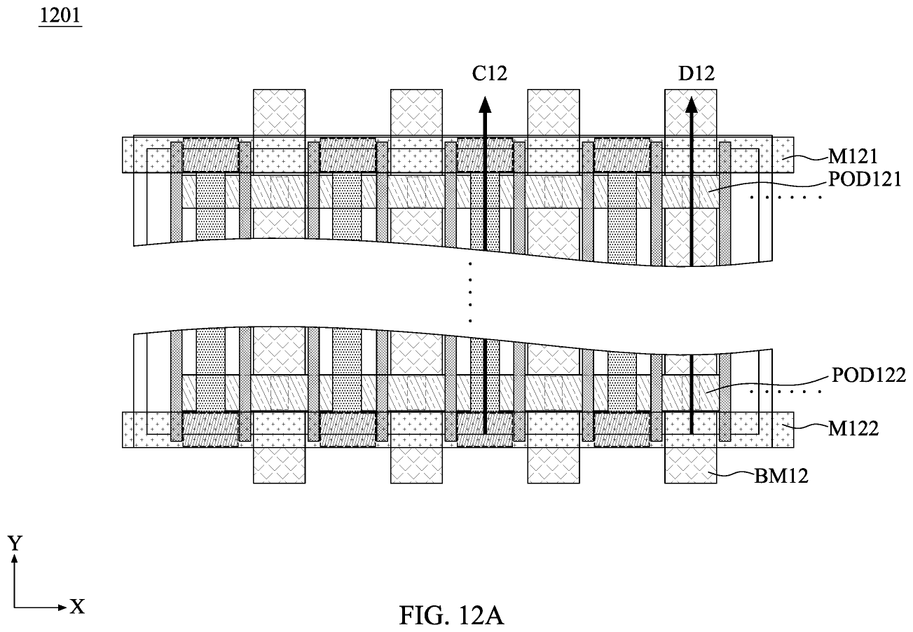

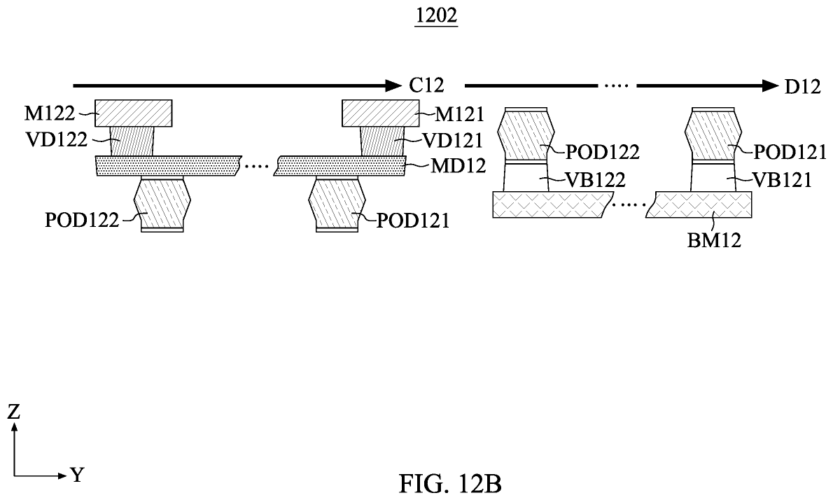

FIG. 12A is a schematic diagram of a design layout of a semiconductor device 1201, in accordance with some embodiments of the present disclosure. The semiconductor device 1201 can correspond to the semiconductor device 801 of FIG. 8A. The semiconductor device 1201 includes two conductive structures POD121 and POD122 that extend along the X direction and include P-type active regions. The semiconductor device 1201 includes two metal structures M121 and M122 extending along the X direction. The semiconductor device 1001 includes a metal structure BM12 extending along the Y direction.

FIG. 12B illustrates cross-section views of a semiconductor device 1202 along the section lines C12 and D12 in FIG. 12A, in accordance with some embodiments of the present disclosure. The semiconductor device 1202 can correspond to the semiconductor device 1201 of FIG. 12A.

Along the section line C12, the metal layer structure MD12 is formed on the conductive structures POD121 and POD122. The metal layer structure MD12 extends along the Y direction. The metal structure M122 and the via structure VD122 are formed on the metal layer structure MD12. The metal structure M121 and the via structure VD121 are formed on the metal layer structure MD12. The metal structures M121 and M122 are formed on the front side of the wafer. Along the section line D12, the conductive structure POD122 and the via structure VB122 are formed on the metal structure BM12. The conductive structure POD121 and the via structure VB121 are formed on the metal structure BM12. The metal structure BM12 is formed on the back side of the wafer. The metal structures M121 and M122 are formed on the front side of the wafer. The metal structure BM12 is electrically connected to the source S81 of FIG. 8A. The metal structures M121 and M122 are electrically connected to the drain D81 of FIG. 8A.

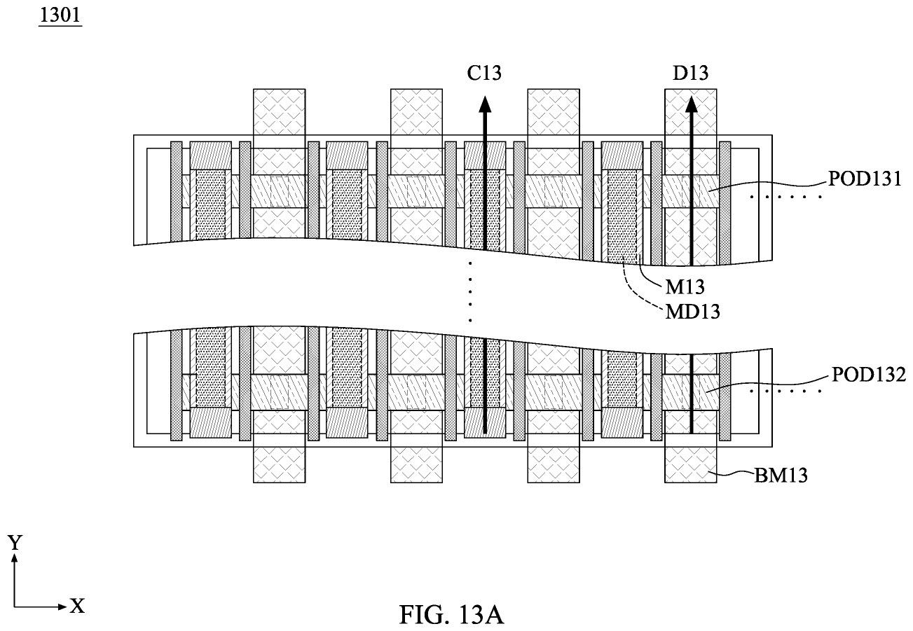

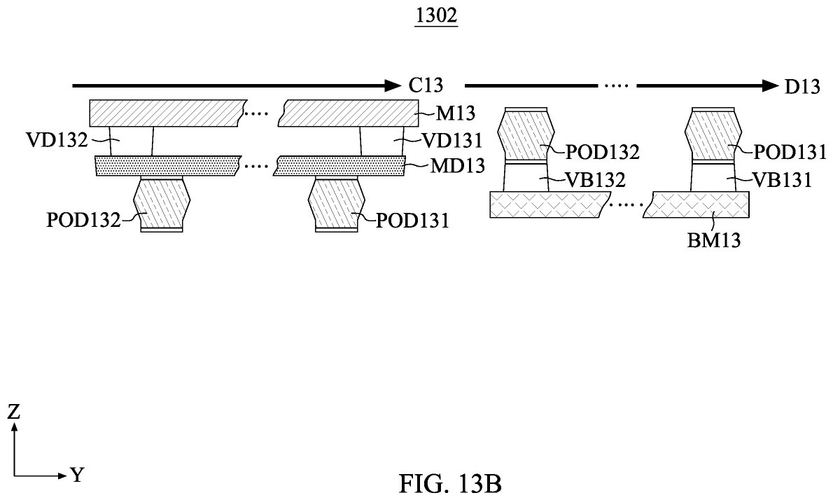

FIG. 13A is a schematic diagram of a design layout of a semiconductor device 1301, in accordance with some embodiments of the present disclosure. The semiconductor device 1301 can correspond to the semiconductor device 801 of FIG. 8A. The semiconductor device 1301 includes two conductive structures POD131 and POD132 that extend along the X direction and include P-type active regions. The semiconductor device 1301 includes a metal structure BM13 extending along the Y direction. The semiconductor device 1301 includes a metal structure M13 extending along the Y direction. The semiconductor device 1301 includes a metal layer structure MD13 extending along the Y direction.

FIG. 13B illustrates cross-section views of a semiconductor device 1302 along the section lines C13 and D13 in FIG. 13A, in accordance with some embodiments of the present disclosure. The semiconductor device 1302 can correspond to the semiconductor device 1301 of FIG. 13A.

Along the section line C13, the via structures VD131 and VD132 are formed between the metal layer structure M13 and the metal layer structure MD13. The metal layer structure MD13 are formed on the conductive structures POD131 and POD132. The metal layer structure M131, the via structures VD131 and VD132 and the metal layer structure MD13 can be formed on the front side of the wafer. Along the section line D13, the conductive structure POD132 and the via structure VB132 are formed on the metal structure BM13. The conductive structure POD131 and the via structure VB131 are formed on the metal structure BM13. The metal structure BM13 is formed on the back side of the wafer.

Some embodiments of the present disclosure provide a semiconductor device formed on a wafer having a front side and a back side. The semiconductor device includes a first back metal structure, a second back metal structure, a first conductive structure and a metal layer structure. The first back metal structure is formed on the back side of the wafer and extends in a first direction. The second back metal structure is formed on the back side of the wafer and extends in the first direction. The second back metal structure is spaced apart from the first back metal structure along a second direction vertical to the first direction. The first conductive structure is formed on the front side of the wafer, which extends in the first direction and is formed above the second back metal structure. The metal layer structure extends in the second direction and is formed above the first conductive structure. The first back metal structure belongs to a first power domain and the second back metal structure belongs to a second power domain different from the first power domain.

Some embodiments of the present disclosure provide a semiconductor device formed on a wafer. The semiconductor device includes a first back metal structure, a first conductive structure, a metal layer structure and a second metal structure. The first back metal structure belongs to a first power domain, and the first back metal structure is formed on a back side of the wafer. The first conductive structure extends in a first direction and is formed above the first back metal structure, and the first conductive structure is P-type. The metal layer structure extends in a second direction vertical to the first direction and is formed above the first conductive structure. The second metal structure belongs to a second power domain different from the first power domain.

Some embodiments of the present disclosure provide a method for manufacturing a semiconductor device. The method includes forming a first back metal structure, extending in a first direction and belonging to a first power domain; forming a second back metal structure, extending in the first direction and belonging to a second power domain different from the first power domain, wherein the second back metal structure is spaced apart from the first back metal structure along a second direction vertical to the first direction; forming a first conductive structure, extending in the first direction and formed above the second back metal structure; and forming a metal layer structure, extending in the second direction and formed above the first back metal structure and the first conductive structure, wherein the first back metal structure and the second back metal structure are formed on a back side of the wafer.

The foregoing outlines structures of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device formed on a wafer having a front side and a back side, comprising:
a first back metal structure formed on the back side of the wafer and extending in a first direction;
a second back metal structure formed on the back side of the wafer and extending in the first direction, wherein the second back metal structure is spaced apart from the first back metal structure along a second direction vertical to the first direction;
a first conductive structure formed on the front side of the wafer, extending in the first direction and formed above the second back metal structure; and
a metal layer structure, extending in the second direction and formed above the first conductive structure, wherein the first back metal structure belongs to a first power domain and the second back metal structure belongs to a second power domain different from the first power domain.

2. The semiconductor device of claim 1, further comprising:
a second conductive structure formed on the front side of the wafer and extending in the first direction, wherein the second conductive structure is formed between the first back metal structure and the metal layer structure; and
a first via structure, formed between the first back metal structure and the second conductive structure.

3. The semiconductor device of claim 2, wherein the first conductive structure is P-type, and the second conductive structure is N-type.

4. The semiconductor device of claim 3, further comprising:
a first front metal structure, extending in the first direction and belonging to the second power domain, wherein the first front metal structure is formed above the metal layer structure and the first conductive structure, and the first front metal structure is formed on the front side of the wafer.

5. The semiconductor device of claim 1, further comprising:
a through via structure, extending in the first direction, wherein the through via structure is formed above the first back metal structure.

6. The semiconductor device of claim 5, further comprising:
a second front metal structure, extending in the first direction and belonging to the second power domain, wherein the second front metal structure is formed above the metal layer structure and the first conductive structure, and the second front metal structure is formed on a front side of the wafer.

7. The semiconductor device of claim 6, further comprising:
a third conductive structure, extending in the first direction and formed between the second back metal structure and the metal layer structure, wherein the third conductive structure is P-type.

8. The semiconductor device of claim 1, wherein the first power domain is configured to transmit power from a power supply to a switch cell, the second power domain is configured to transmit power from the switch cell to a standard cell, and the second power domain can be cut off by the switch cell.

9. A semiconductor device formed on a wafer, comprising:
a first back metal structure, belonging to a first power domain, and the first back metal structure is formed on a back side of the wafer;
a first conductive structure, extending in a first direction and formed above the first back metal structure, wherein the first conductive structure is P-type;
a metal layer structure, extending in a second direction vertical to the first direction and formed above the first conductive structure; and
a second metal structure, belonging to a second power domain different from the first power domain.

10. The semiconductor device of claim 9, wherein the second metal structure comprises a second back metal structure formed on the back side of the wafer, and the first conductive structure is formed above the second back metal structure.

11. The semiconductor device of claim 10, wherein the first back metal structure and the second back metal structure extend in the first direction.

12. The semiconductor device of claim 10, wherein the first back metal structure and the second back metal structure extend in a second direction perpendicular to the first direction.

13. The semiconductor device of claim 9, wherein the second metal structure comprises a second front metal structure formed on a front side of the wafer, and the second front metal structure is formed above the metal layer structure.

14. The semiconductor device of claim 13, wherein the first back metal structure and the second front metal structure extend in the first direction.

15. The semiconductor device of claim 13, wherein the first back metal structure extends in the first direction, and the second front metal structure extends in the second direction.

16. The semiconductor device of claim 13, wherein the first back metal structure extends in the second direction, and the second front metal structure extends in the first direction.

17. The semiconductor device of claim 13, wherein the first back metal structure and the second front metal structure extend in the second direction.

18. A method for manufacturing a semiconductor device on a wafer, comprising:
forming a first back metal structure, extending in a first direction and belonging to a first power domain;
forming a second back metal structure, extending in the first direction and belonging to a second power domain different from the first power domain, wherein the second back metal structure is spaced apart from the first back metal structure along a second direction vertical to the first direction;
forming a first conductive structure, extending in the first direction and formed above the second back metal structure; and
forming a metal layer structure, extending in the second direction and formed above the first back metal structure and the first conductive structure, wherein the first back metal structure and the second back metal structure are formed on a back side of the wafer.

19. The method of claim 18, further comprising:
forming a second conductive structure, extending in the first direction, wherein the second conductive structure is formed between the first back metal structure and the metal layer structure; and
forming a first via structure, formed between the first back metal structure and the second conductive structure.

20. The method of claim 18, further comprising:
forming a through via structure, extending in the first direction, wherein the through via structure is formed above the first back metal structure.
